(19) United States
(12) Patent Application Publication
(10) Pub. No.: US 2001/0013772 A1
(43) Pub. Date: Aug. 16, 2001

(54) Chuck device and chuck method

(76) Inventors: Masahiko Sugiyama, Nirasaki-shi (JP); Yutaka Akaike, Nirasaki-shi (JP)

Correspondence Address: Oblon, Spivak, McClelland,, Maier & Neustadt, P.C., Fourth Floor, 1755 Jefferson Davis Highway, Arlington, VA, 22202, US

(21) Appl. No.: 09/740,867

(22) Filed: Dec. 21, 2000

(30) Foreign Application Priority Data
Feb. 15, 2000 (JP) 2000-036360

(51) Int. Cl. G01R 1/00

(52) U.S. Cl. 324/158.1

(57) ABSTRACT

The mounting surface of a chuck is divided into a plurality of areas by use of grooves. In the chuck, fluid paths are formed. One end of each of the fluid paths is opened in a corresponding one of the grooves and the other end thereof is opened on the outer surface of the chuck. A gas cylinder and vacuum drawing mechanism are selectively connected to the other ends of the fluid paths via solenoid valves.

### CROSS-REFERENCE TO RELATED APPLICATIONS

This application is based upon and claims the benefit of priority from the prior Japanese Patent Application No. 2000-036360, filed Feb. 15, 2000, the entire contents of which are incorporated herein by reference.

### BACKGROUND OF THE INVENTION

This invention relates to a chuck device and chuck method used for subjecting, for example, an integrated circuit formed on a to-be-tested object such as a semiconductor wafer to a probe test.

In the following description, a to-be-tested object such as an LCD or a semiconductor wafer is simply referred to as a “wafer” and a to-be-measured element such as an integrated circuit formed on the to-be-tested object is simply referred to as an “IC chip”.

More specifically, this invention relates to a chuck device and chuck method capable of stably fixing a wafer without positional deviation and lowering the thermal resistance between a chuck and a wafer under probe test.

A probe device is used for making the probe test for IC chip(s). As shown in FIG. 5, in the conventional probe device, the wafer is placed on a wafer chuck 1. A probe card 2 is disposed above the wafer chuck. Probes 2A of the probe card 2 are brought into electrical contact with electrode pads of IC chip(s) formed on the wafer W by raising the wafer chuck 1. In this state, the electric characteristics of the IC chip(s) are tested by use of a tester connected to the probes 2A. As shown in FIG. 5, the wafer chuck 1 is fixed on X and Y stages 3. In FIG. 5, the X and Y stages are shown as an integrated structure as a matter of convenience for explanation. If the X and Y stages 3 are reciprocally moved in X and Y directions, the wafer chuck 1 can also be reciprocally moved in the X and Y directions. An elevator 4 for the main chuck 1 is fixed on the X and Y stages 3. On the X and Y stages 3, the wafer chuck 1 is vertically moved in a Z direction by means of the elevator 4. For example, the elevator 4 can include a motor 4B provided in a cylindrical container 4A, a ball screw 4C rotated by the motor 4B and a nut member (not shown) which is engaged with the ball screw 4C. By rotating the ball screw 4C, the wafer chuck 1 is vertically moved in the Z direction in FIG. 5. By the vertical movement thereof, the probe 2A is brought into contact with or separated from the wafer W.

The wafer chuck 1 is provided with cooling means (not shown). The cooling means cools the wafer chuck 1 and the wafer W placed on the wafer chuck 1. Particularly, when IC chips which generate a large amount of heat are tested, the wafer cannot be sufficiently cooled because of the presence of a gap between the surface of the wafer chuck 1 and the wafer W. Therefore, there is proposed a technique for supplying gas (for example, helium gas) which has high thermal conductivity into the gap between the wafer W and the wafer chuck 1 and enhancing the cooling effect by the wafer chuck (Jpn. Pat. Appln. KOKAI Publication No. 7-263526).

However, if gas having high thermal conductivity is supplied into the gap between the wafer W and the wafer chuck 1, it becomes difficult to stably fix the wafer on the wafer chuck 1. Therefore, in the technique described in the above publication, means for attracting the wafer on the wafer chuck by vacuum is provided.

### BRIEF SUMMARY OF THE INVENTION

In the technique described in the above publication, gas is supplied into the gap between the wafer and the wafer chuck in order to enhance the cooling effect of the wafer and the wafer is attracted to the wafer chuck by vacuum. However, the wafer cannot be stably held on the wafer chuck. If the degree of vacuum in the gap between the wafer and the wafer chuck is increased in order to stably hold the wafer on the wafer chuck, there occurs a possibility that supplying of thermally conductive gas into the gap between the wafer and the wafer chuck becomes meaningless.

As schematically shown in FIG. 6, the contact surfaces of the wafer W and the wafer chuck 1 are mirror-finished. However, since the contact surfaces are irregular when they are microscopically observed, minute gaps are formed between the contact surfaces. If the degree of vacuum in the minute gaps is increased, the thermal resistance between the contact surfaces is increased even when thermally conductive gas is supplied into between the contact surfaces.

Further, at present, since the integrated circuits are formed with a superfine structure and the number of electrode pads is increased, the pitch between the electrode pads becomes smaller. Accordingly, the number of probes 2A is increased and if the technique described in the above publication is used, high needle pressure is applied from the probes 2A to the wafer W place on the wafer chuck 1. As a result, the needle pressure inclines the wafer chuck 1 as exaggeratedly indicated by a one-dot-dash line in FIG. 5 in a case where the peripheral portion of the wafer W is tested. The wafer W slides on the wafer chuck 1. In an extreme case, there occurs a possibility that the probes 2A are separated from the electrode pads of the wafer W. When IC chips which generate a large amount of heat are tested, a probe card 2′ having inclined probes 2′A as schematically shown in FIG. 7 may be used in some cases. If the probe card 2′ is used to make a test, the wafer W slides on a wafer chuck (not shown) by needle pressures from the probes 2′A acting in a direction indicated by arrows in FIG. 7.

An object of this invention is to solve the above problems.

The other object of this invention is to stably fix a wafer and prevent the positional deviation of the wafer.

The other object of this invention is to efficiently cool IC chips which generate a large amount of heat even if the IC chips are tested.

The other objects and advantages are described in the following specification and part thereof will be obviously understood from the disclosure or obtained by embodying this invention. The objects and advantages are realized and attained by means particularly pointed out here and a combination thereof.

According to a first aspect of this invention, there is provided a chuck device for probe-testing a plurality of integrated circuits formed on a semiconductor wafer, comprising a wafer chuck on which the semiconductor wafer is mounted, the wafer chuck having a mounting surface on which the semiconductor wafer is mounted and a cooling mechanism disposed in the wafer chuck, for cooling the semiconductor wafer; a plurality of grooves formed in the mounting surface of the wafer chuck, the plurality of grooves being formed to divide the mounting surface into a plurality of areas; a plurality of supply/exhaust paths formed in the wafer chuck, one end of each of the supply/exhaust paths being opened in the groove and the other end thereof being opened on the peripheral surface of the wafer chuck; and a switching mechanism for selectively connecting a supply source of fluid which has high thermal conductivity and vacuum drawing means to each of the supply/exhaust paths.

In the above chuck device, it is preferable that the wafer chuck probe-tests the plurality of integrated circuits formed on the semiconductor wafer while indexing the semiconductor wafer.

In the above chuck device, it is preferable that the grooves are arranged in a direction of indexing of the semiconductor wafer.

In the above chuck device, it is preferable that the groove is formed as an annular groove.

In the above chuck device, it is preferable that the switching means is a solenoid valve.

In the above chuck device, it is preferable that the plurality of grooves define a plurality of areas by radially dividing the mounting surface from the center thereof.

In the above chuck device, it is preferable that the plurality of grooves define a plurality of areas by dividing the mounting surface into four areas by use of cross-shaped lines.

In the above chuck device, it is preferable that the plurality of grooves are also formed inside each of the radial areas.

According to a second aspect of this invention, there is provided a wafer chuck method for mounting a semiconductor wafer having a plurality of integrated circuits formed thereon on a wafer chuck having a cooling mechanism therein and probe-testing the plurality of integrated circuits while indexing the semiconductor wafer, comprising the steps of supplying a fluid having high thermal conductivity into a gap between the wafer chuck and a rear surface portion of the semiconductor wafer on which the plurality of integrated circuits under probe test are arranged; and drawing a vacuum in a gap between the wafer chuck and a rear surface portion of the semiconductor wafer on which the plurality of integrated circuits which are not placed under probe test are arranged.

In the above chuck method, it is preferable that the fluid having high thermal conductivity is helium gas.

According to a third aspect of this invention, there is provided a chuck device for mounting a to-be-tested object thereon, comprising a chuck having an upper surface on which the to-be-tested object is mounted, a cooling mechanism for cooling the to-be-tested object being provided in the chuck, a plurality of grooves being formed in the upper surface of the chuck and the plurality of grooves being formed to divide the upper surface of the chuck into a plurality of areas and formed without communication with one another; and a plurality of supply/exhaust paths provided in the chuck, one end of each of the supply/exhaust paths being opened in the groove and the other end thereof being opened on the peripheral surface of the chuck.

It is preferable that the chuck device further comprises a switching mechanism connected to the other end of each of the supply/exhaust paths and the switching mechanism selectively connects a thermal conductive fluid supplying mechanism and vacuum drawing mechanism to the other end.

It is preferable that the to-be-tested object of the chuck device has a plurality of to-be-measured elements on the surface thereof and each of the grooves is formed to substantially surround a corresponding one of the areas in which those of the to-be-measured elements which are collectively tested are arranged.

In the chuck device, it is preferable that the grooves are formed to divide the upper surface of the chuck into a plurality of areas which are arranged in parallel to a direction in which the to-be-tested object is indexed.

In the chuck device, it is preferable that the other end of each of the supply/exhaust paths is opened on at lest one of the peripheral side surface and the peripheral bottom surface of the chuck.

According to a fourth aspect of this invention, there is provided a chuck device for mounting a to-be-tested object thereon, comprising a chuck having an upper surface on which the to-be-tested object is mounted and a cooling mechanism provided therein, for cooling the to-be-tested object, the upper surface including a central area for mounting a to-be-tested object having a first diameter and at least one annular area concentrically arranged outside the central area, for mounting a to-be-tested object having second diameter larger than the first certain diameter, a plurality of grooves being formed in the upper surface and the plurality of grooves being formed to divide the central area and the annular area of the upper surface of the chuck into a plurality of small areas and formed without communication with one another; and a plurality of supply/exhaust paths provided in the chuck, one end of each of the supply/exhaust paths being opened in the groove and the other end thereof being opened on the peripheral surface of the chuck.

It is preferable that the supply/exhaust paths includes supply/exhaust paths for the central area whose one end is opened in the groove in the central area and supply/exhaust paths for the annular area whose one end is opened in the groove in the annular area and the chuck device further comprises first and second switching mechanisms connected to the other ends of the plurality of supply/exhaust paths, the first switching mechanism selectively connecting a thermal conductive fluid supplying mechanism and vacuum drawing mechanism to the other end of the supply/exhaust path for the central area and the second switching mechanism selectively connecting the thermal conductive fluid supplying mechanism and vacuum drawing mechanism to the other ends of the supply/exhaust path for the central area and the supply/exhaust path for the annular area.

In the chuck device, it is preferable that the to-be-tested object has a plurality of to-be-measured elements on the surface thereof and each of the grooves is formed to substantially surround a corresponding one of the areas in which those of the plurality of to-be-measured elements which are simultaneously tested are arranged.

In the chuck device, it is preferable that the to-be-tested object has a plurality of to-be-measured elements on the surface thereof and each of the grooves is formed to divide the chuck surface into a plurality of areas arranged in parallel to a direction in which the to-be-tested object is indexed.

According to a fifth aspect of this invention, there is provided a chuck method for testing the electrical characteristic of to-be-measured elements formed on a to-be-tested object, comprising the steps of placing the to-be-tested object on a chuck having a cooling mechanism therein; and testing a plurality of to-be-measured elements by repeatedly effecting the operation for testing part of the plurality of to-be-measured elements formed on the to-be-tested object and moving the to-be-tested object; wherein a thermal conductive fluid is supplied into a gap between the chuck surface and a rear surface of the area of the to-be-tested object on which part of the to-be-measured elements which are now tested are arranged and a vacuum is drawn in a gap between the chuck surface and a rear surface of the other area thereof.

In the chuck method, it is preferable that the steps of supplying the fluid having the high thermal conductivity to the rear surface of the area on the to-be-tested object and attracting the rear surface of the other area thereof towards the chuck by vacuum are effected by selectively connecting a thermal conductive fluid supplying mechanism and vacuum drawing mechanism to the gap between the rear surface of the to-be-tested object and the surfaces of the respective small areas of the chuck.

According to a sixth aspect of this invention, there is provided a probe card comprising a probe plate; a large number of probes provided on the undersurface of the probe plate; and a thermal conductive medium layer formed on at least part of the surface on which the probes are provided.

In the probe card, the thermal conductive medium layer is formed on part of the surface on which the probes are provided and it is preferable that a cooling medium is supplied to a portion of the probe plate on which the thermal conductive medium layer is not formed.

In the probe card, it is preferable that a circulating path for circulating the cooling medium is formed in the probe plate.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a plan view showing one embodiment of a chuck device of this invention;

FIG. 2 is a cross sectional view taken along the II-II line of the chuck device shown in FIG. 1;

FIG. 3 is a plan view showing the main portion of another embodiment of a chuck device of this invention;

FIG. 4 is a plan view showing the main portion of still another embodiment of a chuck device of this invention;

FIG. 5 is an explanatory view showing the inclined state of a wafer chuck when the probe test is made by use of the conventional wafer chuck;

FIG. 6 is a cross sectional view schematically showing the contact state between the wafer chuck and the wafer;

FIG. 7 is an explanatory view showing the relation between the probe and the wafer when the probe test is made by use of a probe card having the inclined probes;

FIG. 8 is a plan view showing an example of the arrangement of a semiconductor wafer and integrated circuits formed on the semiconductor wafer; and

FIG. 9 is a plan view showing another embodiment of a chuck device of this invention.

### DETAILED DESCRIPTION OF THE INVENTION

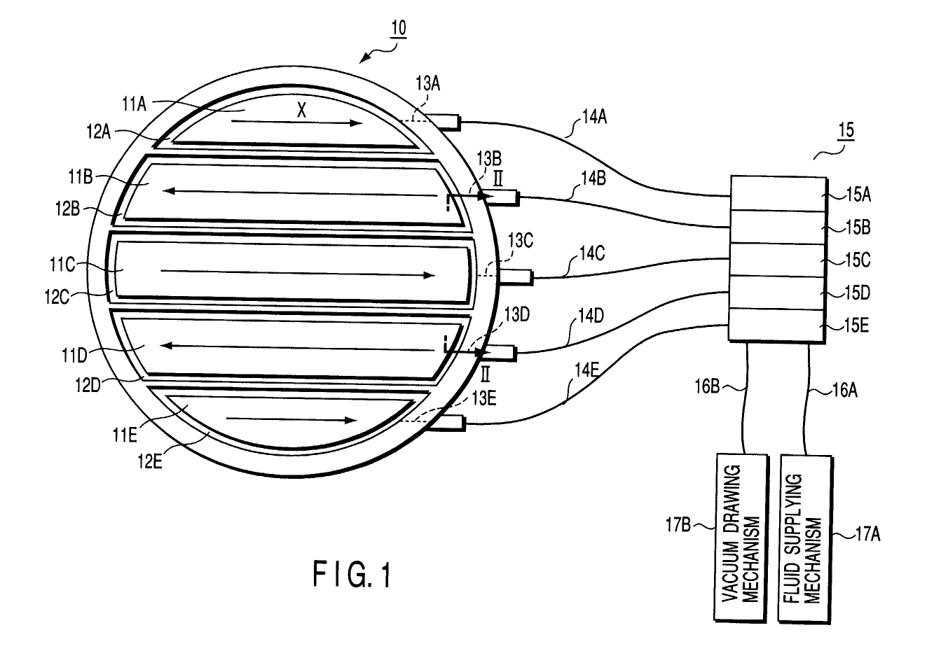

This invention will now be described based on embodiments shown in FIGS. 1 to 4. This invention relates to a chuck device and chuck method for mounting a to-be-tested object and used in a device for testing the electrical characteristics of a plurality of to-be-measured elements formed on the to-be-tested object. In the following description, as a matter of convenience for explanation, the to-be-tested object and the to-be-measured element are referred as a wafer and an IC chip. Nonetheless, the invention is not limited to this case and an LCD may be used as the to-be-tested object, for example.

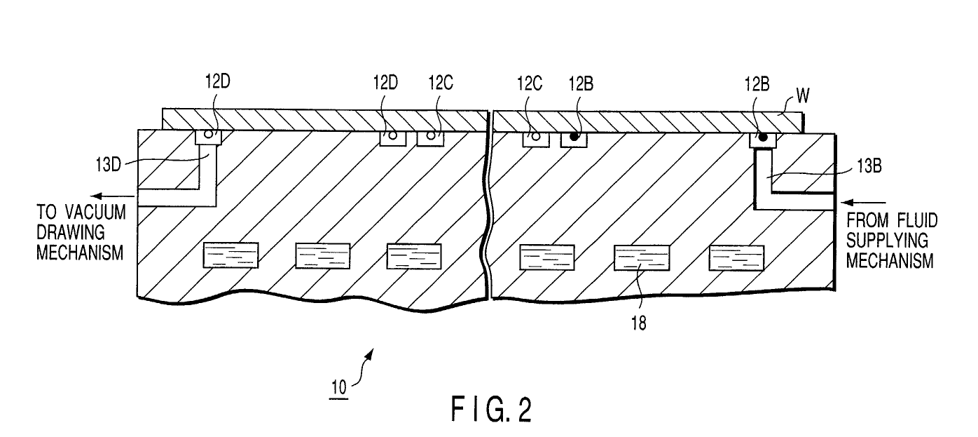

FIG. 1 is a plan view showing one embodiment of a chuck device 10 of this invention and FIG. 2 is a cross sectional view taken along the II-II line of the chuck device 10 shown in FIG. 1.

As shown in FIG. 8, a plurality of IC chips which are to-be-measured elements are formed on a wafer W. For example, the chuck device 10 of this embodiment can be formed of metal such as copper or copper alloy which has high thermal conductivity. As shown in FIG. 1, the mounting surface of the chuck device 10 is divided into a plurality of (in FIG. 1, five) areas 11A, 11B, 11C, 11D and 11E arranged in a direction indicated by an arrow in which the wafer is indexing. It is preferable that each of the areas 11A, 11B, 11C, 11D and 11E is formed in a long and narrow shape in the indexing direction. A probe card (not shown) is arranged above the wafer chuck 10. A plurality of IC chips in each area are collectively tested by use of a tester (not shown) via the probe card. In the test mode, it is possible to collectively test the IC chips in each area or sequentially test a plurality of IC chips of the respective areas 11A, 11B, 11C, 1D and 11E in each step of indexing the wafer W.

Grooves (for example, annular grooves) 12A, 12B, 12C, 12D and 12E can be formed along the periphery of the respective areas around the areas 11A, 11B, 11C, 11D, 11E. The width and depth of the groove can be adequately selected according to the position thereof on the chuck. A solenoid valve 15 is driven by means of a control device operated according to a preset program. The solenoid valve 15 connects a gas cylinder or vacuum pump to each annular groove. A fluid (for example, helium gas) having high thermal conductivity is supplied into a gap between the chuck and the wafer W or a vacuum is drawn in the gap. In FIG. 2, it is indicated that the annular grooves 12B indicated by ● marks are supplied with helium gas and a vacuum is drawn in the annular grooves 12C, 12D indicated by marks.

As shown in FIGS. 1, 2, supply/exhaust paths 13A, 13B, 13C, 13D and 13E are formed in the chuck device 10. One end of each of the supply/exhaust paths is opened in a corresponding one of the annular grooves 12A, 12B, 12C, 12D and 12E and the other end thereof is opened on the peripheral side surface or peripheral bottom surface of the chuck device 10. Pipes 14A, 14B, 14C, 14D and 14E are connected to the side surface openings of the chuck device 10. Solenoid valves 15A, 15B, 15C, 15D, 15E are connected to the respective supply/exhaust paths via the pipes. As shown in FIG. 1, the solenoid valves 15A, 15B, 15C, 15D and 15E can be formed in an integrated form. A thermally conductive fluid supplying source (gas cylinder) 17A is connected to the side surface of the solenoid valve via a supply pipe 16A and a vacuum drawing mechanism (vacuum pump) 17B is connected to the side surface of the solenoid valve via an exhaust pipe 16B. The fluid supplying source 17A and vacuum drawing mechanism 17B are alternately connected via the solenoid valve. For example, when helium gas is supplied to the annular groove 12A, the pipe 14A is connected to the fluid supplying source 17A via the solenoid valve 15A. When the annular groove 12A is evacuated, the pipe 14A is connected to the vacuum drawing mechanism 17B via the solenoid valve 15A.

For example, as shown in FIG. 2, a circulating path 18 for a cooling medium such as ethylene glycol or water is formed in the chuck device 10. Both ends of the circulating path 18 are opened on the peripheral surface of the chuck device 10. A heat exchanger (not shown) is connected to the openings of the circulating path 18 via pipes (not shown). The cooling medium cooled by the heat exchanger is circulated in the circulating path 18 of the chuck device 10 to cool the chuck device 10.

Next, the operation of the device is explained. As shown in FIG. 2, the wafer W is placed on the chuck device 10. The solenoid valves 15A, 15B, 15C, 15D and 15E are operated and the pipes 14A, 14B, 14C, 14D and 14E are communicated with the vacuum pump. Air in the annular grooves 12A, 12B, 12C, 12D and 12E sealed by the undersurface of the wafer W is exhausted and the wafer W is attracted on the chuck device 10 by vacuum force. The wafer W is aligned with the probe card. When the probe test is made, the cooling medium circulating in the circulating path 18 cools the chuck device 10.

After this, the chuck device 10 is moved and an IC chip (for example, the left end portion of the area 11A shown in FIG. 1) which is to be first tested is placed directly below the probe card. Then, the chuck device 10 is raised and the electrodes of the IC chip(s) which is treated as a to-be-measured object are brought into electrical contact with the respective probes of the probe card. Before making the electrical contact, the gas cylinder 17A is connected to the supply/exhaust path 13A, pipe 14A communicating with the annular groove 12A surrounding the area in which the element treated as the to-be-measured object is arranged and helium gas or air is supplied into the annular groove 12A via the pipe 14A, supply/exhaust path 13A.

Thus, helium gas is filled in the gap between the area 11A and the wafer W. The helium gas is treated as a heat conduction medium to lower the thermal resistance between the area 11A and a plurality of IC chips and the IC chips which are a to-be-tested object on the area 11A are efficiently cooled via the chuck device 10. At this time, even if the wafer chuck 10 is inclined by application of the needle pressure of the probes, the wafer W is fixed on the chuck device 10 by attracting the rear surface of the wafer W lying on the other area which occupies a large portion of the mounting surface of the chuck device 10 by vacuum drawn via the annular grooves 12B, 12C, 12D and 12E. Thus, the wafer W will not be shifted.

When the first to-be-tested object has been tested, the chuck device 10 is lowered, moved in a direction indicated by an arrow X in FIG. 1 and moved to an index feeding position for the next test. Then, the wafer chuck 10 is raised, the probes are brought into electrical contact with a next IC chip(s) and the IC chip is tested. When another IC chip(s) lying in the area 11A is tested, all of the solenoid valves can be set into the same condition as that set when the first IC chip(s) is tested.

When all of the IC chips in the divided area 11A have been tested, the chuck device 10 is moved from the divided area 11A to the next area 11B. IC chips in the area 11B are tested while they are index-fed from the right side to the left side. When the chuck device is moved from the area 11A to the area 11B, connection of the pipe 14A is switched from the gas cylinder to the vacuum pump by means of the solenoid valve 15A and connection of the pipe 14B is switched from the vacuum pump to the gas cylinder by means of the solenoid valve 15B. By the switching operation, a vacuum is drawn in the annular groove 12A of the area 11A and helium gas is supplied into the annular groove 12B of the area 11B. As a result, the thermal resistance between the area 11B and the IC chips in the area 11B is lowered. In the area 11A, like the other areas 11C, 11D and 11E, a vacuum is drawn and the wafer W is attracted on the chuck device 10 by vacuum and stably fixed on the mounting surface of the chuck device 10. When all of the IC chips in the area 11B have been tested, helium gas is supplied to each of the areas 11C, 11D and 11E in this order by use of the solenoid valves in a manner described above to sequentially test the IC chips in each of the areas and the wafer W is attracted by vacuum in the other areas.

As described above, according to this embodiment, the mounting surface of the wafer chuck 10 having the cooling means is divided into the five areas 11A, 11B, 11C, 11D and 11E. The annular grooves 12A, 12B, 12C, 12D and 12E are respectively formed in the areas. The supply/exhaust paths 13A, 13B, 13C, 13D and 13E which are respectively opened in the annular grooves are formed in the wafer chuck 10. The gas cylinder for supplying helium gas and the vacuum pump are interchangeably connected to the respective supply/exhaust paths by use of the solenoid valves 15A, 15B, 15C, 15D and 15E. With the above construction, helium gas is supplied from the chuck device 10 side towards the rear surface of the wafer W on which an IC chip under test lies. On the other hand, the rear surface of the wafer on which IC chips which are not treated as a to-be-tested object can be attracted on the chuck device by vacuum. Therefore, even if the chuck device 10 is inclined by application of the needle pressure from the probes or an inclined probe is used, the wafer W is attracted on the chuck device 10 by vacuum and the wafer W is reliably prevented from being shifted. Further, even when an IC chip(s) which generates a large amount of heat is tested, the IC chip(s) can be efficiently cooled and the test with high reliability can be made since the thermal resistance between the chuck device 10 and the IC chip(s) under probe test can be lowered.

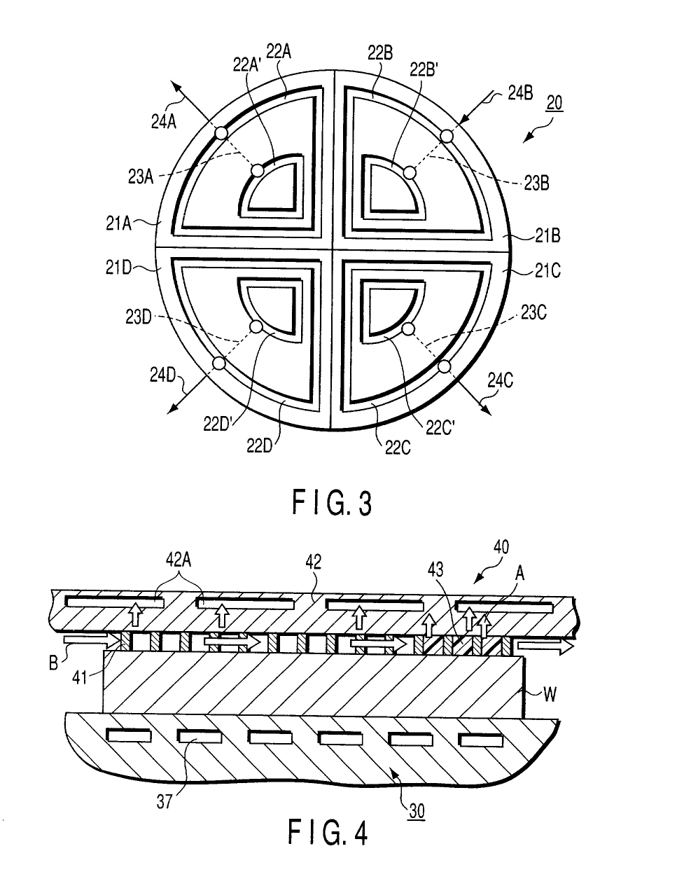

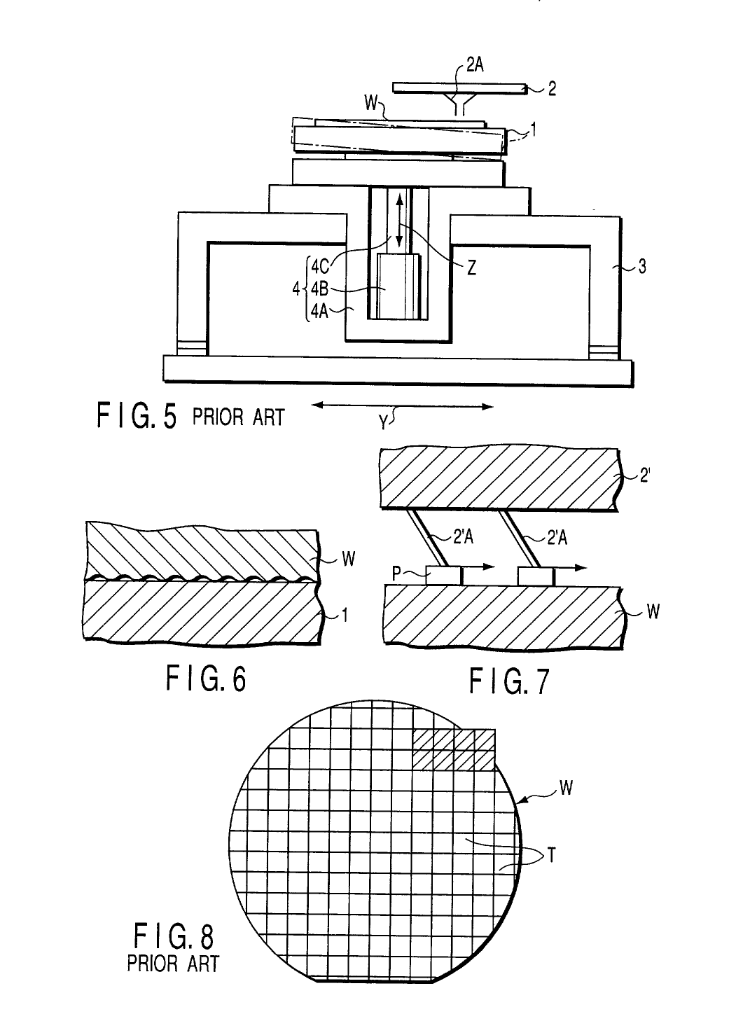

FIG. 3 is a plan view showing another chuck device 20 as another embodiment of this invention. The chuck device 20 is similar to that of the above embodiment except that the shapes of areas lying on the mounting surface and formed by grooves are different. In this embodiment, the mounting surface of the chuck device 20 is divided into a plurality of areas by use of lines extending in a radial direction from the center thereof. As the radially divided areas, three divided areas or four divided areas of the mounting surface can be used. In FIG. 3, the mounting surface is divided into four areas 21A, 21B, 21C and 21D by use of cross-shaped lines. Grooves of various shapes can be formed in the four divided areas according to the basic principle of this invention. As a preferable one of the shapes, in FIG. 3, two annular grooves 22A, 22A′, 22B, 22B′, 22C, 22C′, 22D and 22D′ which are similar in shape to a corresponding one of the areas 21A, 21B, 21C and 21D are formed. In each of the annular grooves, one end of a corresponding one of supply/exhaust paths 23A, 23B, 23C and 23D formed in the respective areas is opened. The opening is indicated by a ◯ mark. The other ends of the supply/exhaust paths are connected to pipes 24A, 24B, 24C, 24D and the pipes are connected to solenoid valves which are the same as those of FIG. 1.

When IC chips on the area 21A are tested, helium gas is supplied into the annular grooves 22A and 22A′ of the area 21A to lower the thermal resistance between the rear surface of the wafer and the area 21A. At this time, in the other areas 21B, 21C and 21D, a vacuum is drawn via the annular grooves and the wafer is attracted on the chuck device by vacuum. Thus, the area in which the IC chips under probe test lies is efficiently cooled and the wafer is attracted on the chuck device 20 by vacuum in the other areas and the positional deviation of the wafer can be prevented without fail. Next, when IC chips lying on the area 21B are tested, the supply/exhaust path connected to the groove in the area 21B is connected to the gas cylinder via the solenoid valve to supply helium gas into the annular grooves 22B and 22B′. A vacuum mechanism is connected to the annular grooves in the other areas and the wafer is attracted on the chuck device by vacuum. Also, in this embodiment, the same effect and operation as in the above embodiment can be attained.

FIG. 4 shows a still another embodiment of this invention. A chuck device 30 can be constructed in a manner similar to one of the above embodiments. In this embodiment, cooling means and thermal resistance lowering means are provided in a probe card 40. The probe card 40 includes a plurality of probes 41, a probe plate 42 having the probes formed thereon, and a heat transfer medium layer 43 having an excellent insulating property and thermally conductive property and provided under the probe plate 42. The heat transfer medium layer 43 is means for lowering the thermal resistance of an air layer between the probe plate 42 and the wafer W. The heat transfer medium layer 43 can be formed of synthetic resin having an excellent thermally conductive property or synthetic resin in which inorganic granules having an excellent thermally conductive property are added. For example, the heat transfer medium layer 43 is formed in a sheet form and can be arranged over the entire surface of the probe plate 42. Alternatively, it can be partially arranged under the probe plate 42 with a preset distance separated therefrom. The heat transfer medium layer 43 accelerates heat transfer in a direction indicated by an arrow A. In FIG. 4, the probe plate 42 under which the heat transfer medium layer 43 is partially arranged is shown. In a portion in which the heat transfer medium layer 43 is not arranged, a space is provided between the probes 41. By supplying a cooling medium such as cooling air into the space as indicated by an arrow B, the wafer W can be more efficiently cooled. Further, as shown in FIG. 4, a circulating path 42A can be formed in the probe plate 42. By circulating the cooling medium in the circulating path 42A, the wafer W can be more efficiently cooled. Formation of the heat transfer medium layer 43 and supply of the cooling medium into the circulating path 42A can be attained independently or in combination.

In the embodiments described above, the annular grooves are formed in the chuck device. Nonetheless, it is possible to use grooves of a shape different from the annular shape. In short, any shape of grooves can be used if a thermally conductive fluid can be supplied to the IC chip area under test and a vacuum can be drawn to attract the wafer on the chuck device by vacuum in the other areas. The shape of the groove and the number of grooves are not limited. Further, the area in which a plurality of IC chips under test lie is not required to be completely coincident with the area defined by the groove into which a thermally conductive fluid is supplied. To-be-tested elements may be disposed near the outer peripheral portion of the area defined by the groove into which a thermally conductive fluid is supplied. Alternatively, elements which are not to be tested may be arranged near the inner peripheral portion of the groove.

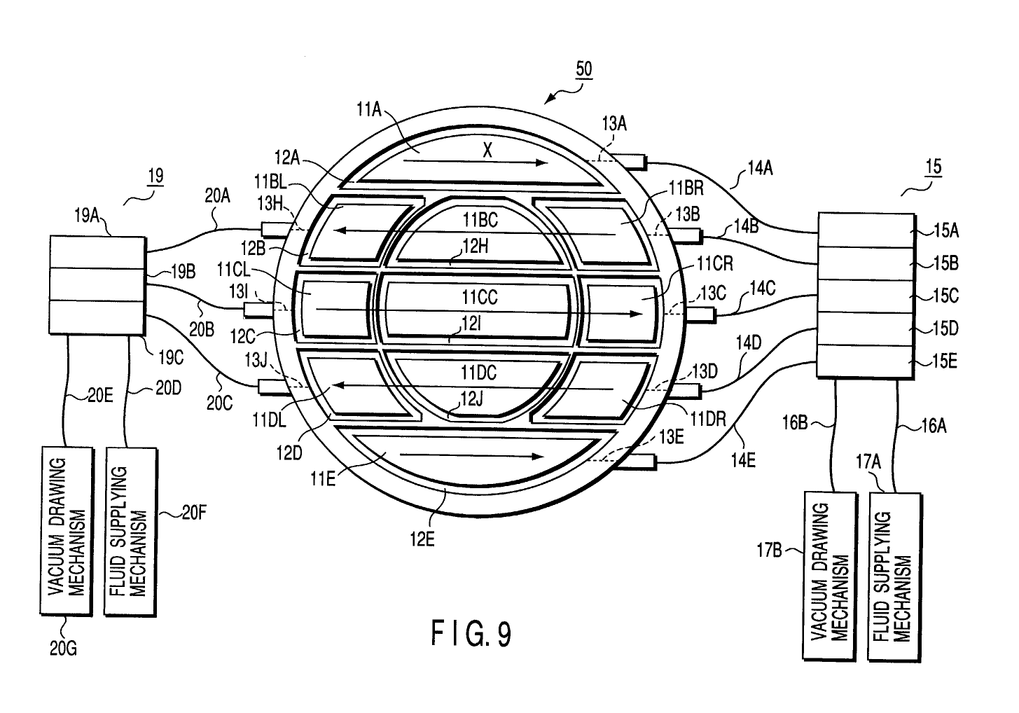

FIG. 9 is a plan view showing another chuck device 50 that is another embodiment of this invention. The chuck device 50 is so constructed that either a to-be-tested object having a large diameter or a to-be-tested object having a small diameter can be placed thereon. The chuck device 50 is similar to that of the above embodiment except that the shapes of areas lying on the mounting surface and formed by grooves are different. In this embodiment, the mounting surface of the chuck device 50 includes a central area (11BC, 11CC, 11DC) having a relatively small diameter and an annular area (11A, 11BL, 11BR, 11CL, 11CR, 11DL, 11DR, 11E) concentrically arranged outside the central area. The central area can be divided into a plurality of small areas (11BC, 11CC, 11DC) and the annular area can be divided into a plurality of small areas (11A, 11BL, 11BR, 11CL, 11CR, 11DL, 11DR, 11E) by use of grooves which are the same as those described before.

If the diameter of the central area is set to correspond to the diameter of a to-be-tested object having a small diameter, the to-be-tested object of the small diameter can be placed on the central area. When the to-be-tested object of the small diameter is placed on the central area, a fluid supply mechanism 20F and vacuum drawing mechanism 20G are selectively connected to supply/exhaust paths (13H, 13I, 13J) for the central area respectively connected to the small areas via a solenoid valve 19 and pipes 20D, 20E.

If the diameter of the annular area is set to correspond to the diameter of a to-be-tested object having a large diameter, the to-be-tested object of the large diameter can be placed on an area which is a combination of the annular area and the central area. To the above annular area, supply/exhaust paths (13A, 13B, 13C, 13D, 13E) for the annular area are connected. A fluid supply mechanism 17A and vacuum drawing mechanism 17B are selectively connected to the supply/exhaust paths for the annular area via a solenoid valve 15 and pipes 14A, 14B, 14C, 14D, 14E.

In FIG. 9, only a single area is formed as the annular area, but a plurality of concentric annular areas can be formed in order to place to-be-tested objects having different diameters. Further, the solenoid valves 15, 19 can be integrally formed.

The chuck device shown in FIG. 9 can be subjected to the probe test in various modes. For example, by indexing the to-be-tested object, to-be-tested elements on the small areas can be sequentially probe-tested. Alternatively, to-be-tested elements can be collectively probe-tested in the unit of the small area. Further, by regarding the linearly arranged small areas (for example, 11BR, 11BC, 11BL) as one area, to-be-tested elements on the above area can be probe-tested.

If the linearly arranged small areas (for example, 11BR, 11BC, 11BL) are regarded as one area and the probe-test is made, it is possible to supply a thermally conductive fluid into a gap between the chuck surface and a portion in which the to-be-measured elements of the to-be-tested object are arranged and at the same time draw a vacuum from a gap between the chuck surface and the other portion on the to-be-tested object with respect to both of the central area and the annular area. Alternatively, it is possible to effect the operation for supplying the thermally conductive fluid and drawing a vacuum in the annular area in the former embodiment and effect only the operation for supplying the thermally conductive fluid in the central area.

According to this invention, it is possible to stably prevent the wafer from being shifted at the test time. Further, according to this invention, even when an IC chip(s) generating a large amount of heat is tested, the IC chip(s) can be efficiently cooled. In this invention, it is possible to place a to-be-tested object having a relatively small diameter and a to-be-tested object having a larger diameter.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A chuck device for probe-testing a plurality of integrated circuits formed on a semiconductor wafer, comprising:
a wafer chuck for mounting the semiconductor wafer thereon, said wafer chuck having a mounting surface on which the semiconductor wafer is mounted and a cooling mechanism arranged in said wafer chuck, for cooling the semiconductor wafer;
a plurality of grooves formed in the mounting surface of said wafer chuck, said plurality of grooves being formed to divide the mounting surface into a plurality of areas;
a plurality of supply/exhaust paths formed in said wafer chuck, one end of each of said supply/exhaust paths being opened in a corresponding one of said grooves and the other end thereof being opened on the peripheral surface of said wafer chuck; and
a switching mechanism for selectively connecting a supply source of a fluid which has high thermal conductivity and vacuum drawing means to each of said supply/exhaust paths.

2. The chuck device according to claim 1, wherein said wafer chuck probe-tests a plurality of integrated circuits formed on the semiconductor wafer while indexing the semiconductor wafer.

3. The chuck device according to claim 2, wherein said grooves are arranged in an indexing direction of the semiconductor wafer.

4. The chuck device according to claim 2, wherein said groove is formed as an annular groove.

5. The chuck device according to claim 2, wherein said switching means is a solenoid valve.

6. The chuck device according to claim 2, wherein said plurality of grooves define a plurality of areas by radially dividing the mounting surface from the center thereof.

7. The chuck device according to claim 2, wherein said plurality of grooves define a plurality of areas by dividing the mounting surface into four areas by use of cross-shaped lines.

8. The chuck device according to claim 6, wherein said plurality of grooves include grooves formed inside each of the radial areas.

9. A chuck method for mounting a semiconductor wafer having a plurality of integrated circuits formed thereon on a wafer chuck having a cooling mechanism therein and probe-testing the plurality of integrated circuits while indexing the semiconductor wafer, comprising the steps of:
supplying a fluid having high thermal conductivity into a gap between the wafer chuck and a rear surface portion of the semiconductor wafer on which the plurality of integrated circuits under probe test are disposed; and
drawing a vacuum in a gap between the wafer chuck and a rear surface portion of the semiconductor wafer on which the plurality of integrated circuits which are not placed under probe test are disposed.

10. The chuck method according to claim 9, wherein the fluid having high thermal conductivity is helium gas.

11. A chuck device for mounting a to-be-tested object thereon, comprising:
a chuck having an upper surface on which the to-be-tested object is mounted, a cooling mechanism for cooling the to-be-tested object being provided in said chuck, a plurality of grooves being formed in the upper surface of said chuck and the plurality of grooves being formed to divide the upper surface of said chuck into a plurality of areas and formed without communication with one another; and
a plurality of supply/exhaust paths provided in said chuck, one end of each of said supply/exhaust paths being opened in a corresponding one of said grooves and the other end thereof being opened on the peripheral surface of said chuck.

12. The chuck device according to claim 11, further comprising a switching mechanism connected to the other end of each of said supply/exhaust paths, said switching mechanism selectively connecting a thermal conductive fluid supplying mechanism and vacuum drawing mechanism to the other end.

13. The chuck device according to claim 11, wherein the to-be-tested object has a plurality of to-be-measured elements formed on the surface thereof and each of said grooves is formed to substantially surround a corresponding one of the areas in which those of the to-be-measured elements which are collectively tested are arranged.

14. The chuck device according to claim 13, wherein said grooves are formed to divide the upper surface of said chuck into a plurality of areas which are arranged in parallel to a direction in which the to-be-tested object is indexed.

15. The chuck device according to claim 11, wherein the other end of each of said supply/exhaust paths is opened on at lest one of the peripheral side surface and the peripheral bottom surface of said chuck.

16. A chuck device for mounting a to-be-tested object thereon, comprising:
a chuck having an upper surface on which the to-be-tested object is mounted and a cooling mechanism provided therein, for cooling the to-be-tested object, the upper surface including a central area for mounting a to-be-tested object having first diameter and at least one annular area concentrically arranged outside the central area, for mounting a to-be-tested object having second diameter larger than the first diameter, a plurality of grooves being formed in the upper surface and the plurality of grooves being formed to divide the central area and the annular area of the upper surface of said chuck into a plurality of small areas and formed without communication with one another; and
a plurality of supply/exhaust paths provided in said chuck, one end of each of said supply/exhaust paths being opened in a corresponding one of said grooves and the other end thereof being opened on the peripheral surface of said chuck.

17. The chuck device according to claim 16, in which said supply/exhaust paths includes supply/exhaust paths for the central area whose one end is opened in a corresponding one of said grooves in the central area and supply/exhaust paths for the annular area whose one end is opened in a corresponding one of said grooves in the annular area and which further comprises first and second switching mechanisms connected to the other ends of said plurality of supply/exhaust paths, said first switching mechanism selectively connecting a thermal conductive fluid supplying mechanism and vacuum drawing mechanism to the other end of each of the supply/exhaust paths for the central area and said second switching mechanism selectively connecting the thermal conductive fluid supplying mechanism and vacuum drawing mechanism to the other ends of each of the supply/exhaust paths for the central area and each of the supply/exhaust paths for the annular area.

18. The chuck device according to claim 16, wherein the to-be-tested object has a plurality of to-be-measured elements formed on the surface thereof and each of the grooves is formed to substantially surround a corresponding one of the areas in which those of the plurality of to-be-measured elements which are simultaneously tested are arranged.

19. The chuck device according to claim 16, wherein the to-be-tested object has a plurality of to-be-measured elements formed on the surface thereof and each of the grooves is formed to divide the chuck surface into a plurality of areas arranged in parallel to a direction in which the to-be-tested object is indexed.

20. A chuck method for testing the electrical characteristic of to-be-measured elements formed on a to-be-tested object, comprising the steps of:
placing the to-be-tested object on a chuck having a cooling mechanism therein; and
testing a plurality of to-be-measured elements by repeatedly effecting the operation for testing part of the plurality of to-be-measured elements formed on the to-be-tested object and moving the to-be-tested object;
wherein a thermal conductive fluid is supplied into a gap between the chuck surface and a rear surface of the area of the to-be-tested object on which part of the to-be-measured elements which are now placed under test are arranged and a vacuum is drawn in a gap between the chuck surface and a rear surface of the other area thereof.

21. The chuck method according to claim 20, wherein said steps of supplying the fluid having the high thermal conductivity to the rear surface of the area on the to-be-tested object and attracting the rear surface of the other area thereof towards the chuck by vacuum are effected by selectively connecting a thermal conductive fluid supplying mechanism and vacuum drawing mechanism to the gap between the rear surface of the to-be-tested object and the surfaces of the respective small areas of the chuck.

22. A probe card comprising:
a probe plate;
a large number of probes provided on an undersurface of said probe plate; and
a thermal conductive medium layer formed on at least part of the surface on which said probes are provided.

23. The probe card according to claim 22, wherein said thermal conductive medium layer is formed on part of the surface on which said probes are provided and a cooling medium is supplied to a portion of the probe plate on which said thermal conductive medium layer is not formed.

24. The probe card according to claim 22, wherein a circulating path for circulating the cooling medium is formed in said probe plate.
